(19) United States
(12) Patent Application Publication
(10) Pub. No.: US 2008/0117708 A1
(43) Pub. Date: May 22, 2008

(54) MEMORY ARRAY WITH BIT LINES COUNTERING LEAKAGE

(75) Inventor: Bohumil Lojek, Colorado Springs, CO (US)

Correspondence Address: SCHNECK & SCHNECK, P.O. BOX 2-E, SAN JOSE, CA, 95109-0005, US

(73) Assignee: Atmel Corporation, San Jose, CA (US)

(21) Appl. No.: 11/561,817

(22) Filed: Nov. 20, 2006

(51) Int. Cl. G11C 8/10

(52) U.S. Cl. 365/230.06

(57) ABSTRACT

Bit lines in a memory array are configured by a select switch matrix to apply the same V_{D} voltage to two adjacent bit lines on the drain side of a selected memory cell for the purpose of blocking charge leakage through the cell adjacent to the selected or addressed cell. The switch matrix features transistors with electrodes connected to bit line segments while control electrodes are connected to control lines from a select decoder. The switch matrix communicates with address decoders for setting switches needed to configure the bit lines as needed with the charge leakage blocking voltage.

### TECHNICAL FIELD

The invention relates to semiconductor memories and in particular to a memory architecture and method for limiting charge leakage.

### BACKGROUND ART

In semiconductor memories, memory cells are arranged in arrays wherein individual cells are addressed by word lines, usually running in the X-direction, and bit lines, usually running in the Y-direction. Each cell includes at least one transistor that stores charge, or is devoid of charge, in a manner indicating a memory state. Individual work lines and bit lines are frequently selected by select transistors that connect lines to a voltage source that can provide electrons or holes to the storage element of the transistor. Word lines and bit lines are shared across the array. While word lines are frequently connected to top level poly control gates of each memory cell, the bit lines are frequently connected to one of the sub-surface source-drain electrodes or first metal lines that are shared with an adjacent memory cell. This shared connection gives rise to a leakage path for charge from the selected memory cell. For example, if stored charge in a memory cell indicates the “zero” state of a memory transistor, the leakage of charge from the cell may cause the memory cell to appear in the opposite digital state, the “one” state. This holds true for all types of memory cells, including non-volatile memory, SRAM, DRAM, etc.

The above problem has been recognized in the prior art. For example, U.S. Pat. No. 6,510,082 to B. Le et. al. deals with the leakage situation by applying the same V_{D} voltage to the drain side bit line of an adjacent cell and the cell being sensed. By applying the same voltage, V_{D}, to both lines, leakage currents become inconsequential. This solution to the problem is termed “charge blocking”.

An object of the invention is to devise a simple memory array architecture and method for charge leakage blocking without using verify circuitry.

### SUMMARY OF INVENTION

The present invention takes the approach of applying the same V_{D} voltage to the drain side of adjacent memory cell and the cell being selected, i.e. two high voltage V_{D} lines, and one virtual ground bit line on the source side of the selected cell, i.e. a low voltage line, without verify circuitry, by using a switch matrix of select transistors. To control the bit lines, select transistors of the array are employed as switches arranged on “quasi word lines”, that are control lines, not actual word lines. The actual word lines control memory cells. On the other hand, quasi word lines control select transistors in the switch matrix wherein at least two adjacent select transistors can be controlled by each quasi word line. All select transistors lie on bit lines between the memory array and voltage sources. In the switch matrix formed by the select transistors, one switch is associated with each bit line and, in the preferred embodiment, two switches are associated with each quasi word line.

The above arrangement effectively blocks charge leakage between a selected memory cell and an adjacent cell on the drain side for as long as select voltage is applied.

### BRIEF DESCRIPTION OF THE DRAWINGS

FIG. 1 is an electrical block diagram of a memory cell array of the present invention.

FIG. 2 is a simplified electrical circuit diagram of the memory cell array shown in FIG. 1.

FIG. 3 is an operational electrical circuit diagram of the memory cell array shown in FIG. 2.

### DESCRIPTION OF PREFERRED EMBODIMENT

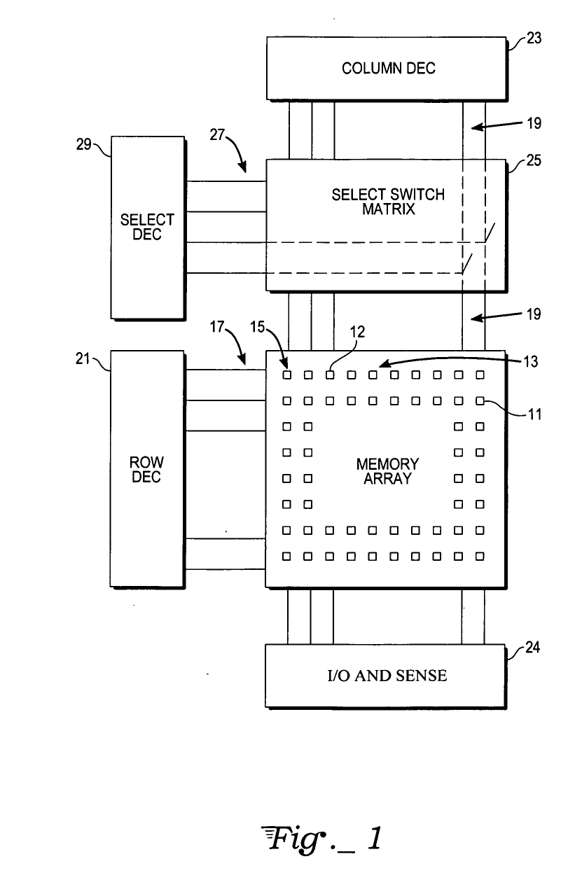

With reference to FIG. 1, an X-Y array 11 of memory cells 12 is shown. The cells are arranged in a plurality of rows and columns. A representative row is the row 13 and a representative column is the column 15. Corresponding to the rows and columns of cells are a plurality of word lines 17 and a plurality of bit lines 19, the word lines and bit lines being used to address individual memory cells. The number of word lines usually corresponds to the number of rows and the number of bit lines corresponds to the number of columns with additional bit lines sometimes needed. The number of word lines and bit lines can vary. One bit line can be a parallel branch of another bit line with a common voltage supplied to both. The two branches are counted as two bit lines.

Voltages on word lines are provided by a row decoder 21 while voltages for the bit lines 19 are provided by column decoder 23, with voltages depending upon a specific operation to be performed at a specific location. Operations can include reading, writing and erasing in the case of non-volatile memory transistors such as EEPROMs. The memory architecture thus far described is common to various types of semiconductor memories, including SRAM, DRAM and non-volatile memories. The present invention is applicable to all such memories. Once a specific memory cell is selected with an address, data from an input-output (I/O) and sense block 24 may be provided to the cell or data may be sent from a selected cell by circuitry associated with the I/O and sense block 24.

In the present invention, the conventional memory architecture is modified by deployment of a select switch matrix 25 between the column decoder 23 and the memory array 11, with a switch in each bit line. The select switch matrix routes voltages from column decoder 23 to the selected memory cell plus an adjacent cell in order to block charge leakage from the selected cell. This is done by opening an closing switchers in the switch matrix. Three bit lines are configured by the switch matrix for this purpose. Switches within the switch matrix are controlled by a select decoder means 29 which operates the switches in the switch matrix 25 in a desired manner using control lines. The selected decoder means 29 is operated by logic that converts selected cell address information from the row and column decoders to bit line switch information. The logic procedure is to actuate switches in the switch matrix such that a bit line adjacent to bit lines on either side of a selected memory cell has the same V_{D} voltage, or a similar voltage such as V_{D} modified by impedance losses, on the drain side of an adjacent cell to the selected cell. This switch configuration yields two adjacent bit lines with V_{D} voltage on the drain side of a selected cell, i.e. on both sides of an adjacent cell, and a virtual ground bit line as the third bit line that is employed. All other bit lines are set to be floating by opening bit line switches.

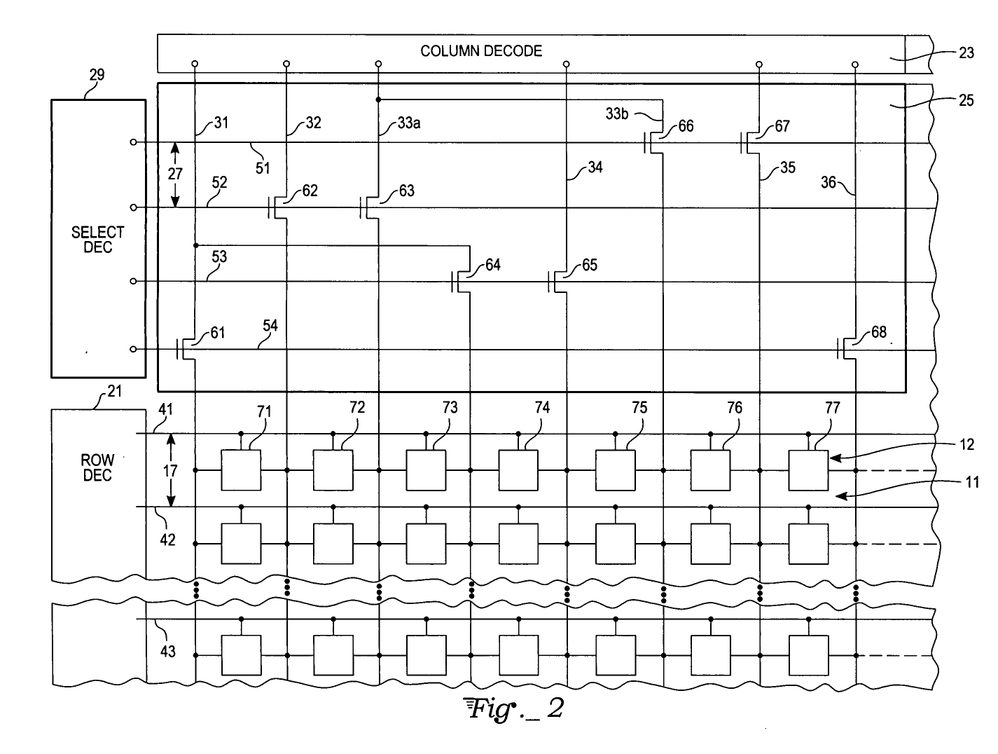

With reference to FIG. 2, bit lines 31-36 are seen to emerge from column decoder 23 into the select switch matrix 25. The switch matrix 25 contains select transistors 61-68, each having a source and drain as bit line terminals. The switches are preferably MOS or CMOS transistors because of superior voltage response but could be other types of transistors. Conductivity between terminals is governed by control lines 51-54 that appear to be similar to word lines 41-43 that operate memory cells. The control lines are termed “quasi word lines” because they are parallel to word lines, running across the array, but are not actual word lines connected to memory cells.

It will be noted that the is one select transistor associated with each bit line. For example, select transistor 61 is associated with bit line 31 and is controlled by control line 54. Select transistor 62 is in bit line 43 and is controlled by control line 52, and so on. It should be noted that it is convenient to have adjacent pairs of select transistors operated by the same control line. For example, select transistors 62 and 63 are controlled by control line 52. The reason for this is that adjacent select transistors will be on the source and drain side of a selected memory cell, such as memory cell 72. Similarly, select transistors 64 and 65 are controlled by control line 53 and adjacent select transistors 66 and 67 are controlled by control line 51. This arrangement of select transistors is not essential, but merely convenient for reducing the number of control lines.

The memory cells 12 in the top row of array 11 are seen to each have three connections. Left and right connections are two bit lines. For example, memory cell 75 has a connection to bit line 34 having select transistor 65 and bit line 33b having select transistor 66. Note that bit line 33b is a branch of bit line 33a, but each bit line has its own switch, although the voltage applied to both bit lines 33a and 33b is the same. The third contact is with a word line. An example of memory cell 75 with an associated word line is the word line 41. It will be noted that source and drain lines are shared between adjacent cells. The bit line 33b running through select transistor 66 is a drain for memory cell 75 but a source for memory cell 76. Such shared bit lines are sometimes called source-drain lines because of the dual function of each line.

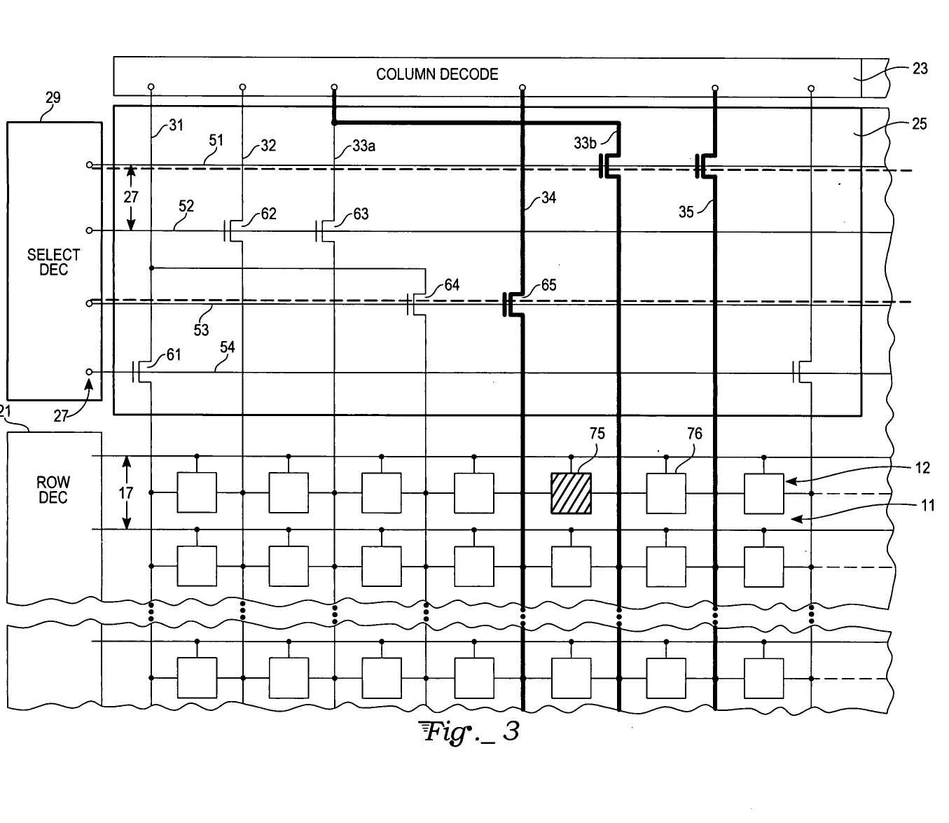

Operation of the circuitry is explained with reference to FIG. 3. In FIG. 3, memory cell 75 is selected for a specified operation such as read, program or erase. The selection is made by appropriate voltages on word line 41 as well as on bit lines 34 and 33b. The bit line voltages are seen by memory cell 75 because the switches 65 and 66 are closed, allowing appropriate voltages to be placed on the lines from column decoder 23. All other switches in the switch matrix are open, except for switch 67 associated with bit line 35. Open switches mean that the bit lines are electrically floating. Switch 67 allows another high voltage, V_{D}, equal to the voltage on bit line 33b to act as a blocking voltage through the memory cell 76. Thus, if there is a low voltage on b it line 34 and a high voltage on bit line 33b so that charge flow in selected memory cell 75 was toward bit line 33b, leakage through the shared electrode, namely bit line 33b and into memory cell 76 will be blocked by the V_{D} voltage on bit line 35. Voltages on the control lines 51-54 are shown in the table below.

TABLE
Voltages in FIG. 3 protect cell 75 from leakage to cell
76. All other cells are floating.

| | |
|---|---|
| Select line 54 = low | Bit line 34 = low |
| Select line 53 = high | Bit line 33b = high |
| Select line 52 = low | Bit line 35 = high |

Note:
Voltage low is virtual ground or GROUND.
Voltage high is V_{D}.

Charge leakage is prevented as long as the voltages shown above are maintained by select transistors. Only one cell at a time is selected and so the select decoder is clocked similarly to row and column decoders.

While the above has described only a few memory cells in an array, it will be realized that there can be thousands of cells in rows and columns of a memory array.

1. A semiconductor memory array comprising:
an array of memory cells having rows and columns;
row and column decoder means for addressing a selected memory cell, the row decoder means having word lines and the column decoder means having bit lines;
a switch matrix having a transistor switch in each bit line, the transistor switch controlled by a control electrode;
a plurality of quasi-word line means for controlling the switches through the control electrode associated with each switch in a memory array wherein three adjacent bit liens can be simultaneously actuated with two of the bit lines being associated with the selected memory cell and the remaining bit line with an adjacent cell.

2. The memory array of claim 1 wherein the memory cells are non-volatile transistors.

3. The memory array of claim 1 wherein the memory cells are SRAM transistors.

4. The memory array of claim 1 wherein the switch matrix has two adjacent switches controlled by the same quasi word line.

5. The memory array of claim 1 wherein the switch matrix is disposed between the column decoder means and the array of memory cells.

6. The memory array of claim 5 wherein transistor switches are arranged to open and close bit lines.

7. In a memory array having rows and columns of memory cells addressed by work lines and bit lines associated with the rows and columns, the improvement comprising:
a matrix of select switches, with a select switch associated with each bit line of an array of memory cells to open and close the bit line;
a plurality of control lines connected to the select switches as quasi word lines but outside of the memory cells; and
a select decoder means connected to the control lines for selectively opening and closing the select switches to apply a voltage to a bit line adjacent to a selected cell as well as a similar voltage to an adjacent line associated with the selected cell whereby charge leakage from the selected cell is blocked.

8. The array of claim 7 wherein the select switches are MOS transistors.

9. The array of claim 7 wherein the memory cells comprise non-volatile transistors.

10. The array of claim 7 wherein the memory cells comprise SRAM transistors.

11. The array of claim 7 wherein a plurality of pairs of adjacent select switches are each on the same control line with two switches on each control line.

12. The array of claim 7 wherein said control lines run parallel to the word lines.

13. The array of claim 7 wherein the select decoder applies voltage to a bit line on the drain side of a cell adjacent to a selected cell as well as two voltages to bit lines associated with the selected cell.

14. A method of configuring bit lines for blocking charge leakage from a selected memory cell to an adjacent cell in a memory array comprising:
deploying a switch in each bit line responsive to a signal on a control line;
selecting a memory cell in the memory array using bit lines and word lines;
actuating switches in three adjacent bit lines disposed on opposite sides of a selected cell and on the drain side of an adjacent cell; and
configuring voltages on the three adjacent bit lines with either a high voltage or a low voltage whereby two voltages on opposite sides of the adjacent cell are high voltages, and the remaining voltage is a low voltage, thereby blocking charge leakage from the selected cell to the adjacent cell.

15. The method of claim 14 further defined by operating said switches with control lines running parallel to the word lines.

16. The method of claim 15 wherein deploying a switch in each bit line comprises connecting a MOS transistor with source and drain electrodes to open and close the bit line, the MOS transistor having a control electrode.

17. The method of claim 16 wherein actuating of the switches comprises using the control electrode of the MOS transistor to induce conductivity between source and drain electrodes.
